(19) United States
(12) Patent Application Publication
(10) Pub. No.: US 2008/0169501 A1
(43) Pub. Date: Jul. 17, 2008

(54) FLASH MEMORY DEVICE WITH HYBRID STRUCTURE CHARGE TRAP LAYER AND METHOD OF MANUFACTURING SAME

(75) Inventors: Jun-kyu YANG, Seocho-gu (KR); Seung-jae BAIK, Seocho-gu (KR); Jin-tae NOH, Suwon-si (KR); Seung-hyun LIM, Yongin-si (KR); Kyong-hee JOO, Seongnam-si (KR); Zong-liang HUO, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/776,723

(22) Filed: Jul. 12, 2007

(30) Foreign Application Priority Data
Jan. 11, 2007 (KR) 10-2007-0003395

(51) Int. Cl. H01L 29/788; H01L 21/3205

(52) U.S. Cl. 257/321; 438/585; 257/E21.294; 257/E29.3

(57) ABSTRACT

A flash memory device including a hybrid structure charge trap layer and a related method of manufacture are disclosed. The charge trap layer includes at least one hybrid trap layer including a first trap layer formed from a first material having a first band gap energy, and a plurality of nano dots separated from each other such that each nano dot is at least partially encircled by the first trap layer, the plurality of nano dots being formed from a second material having a second band gap energy lower than the first band gap energy.

### CROSS-REFERENCE TO RELATED PATENT APPLICATION

This application claims the benefit of Korean Patent Application No. 10-2007-0003395, filed on Jan. 11, 2007, the subject matter of which is incorporated herein in its entirety by reference.

### BACKGROUND OF THE INVENTION

1. Field of the Invention

The present invention relates to a method of manufacturing a semiconductor memory device. More particularly, the invention relates to a flash memory device including a charge trap layer with trap sites storing charge, and a method of manufacturing same.

2. Description of the Related Art

Flash memory incorporating a charge trapping layer is one form of nonvolatile memory commonly used in many types of host devices and applications, such as mobile telecommunication systems, memory cards, etc.

A conventional charge-trap type flash memory device has a gate stack structure implemented by sequentially stacking a tunneling insulating layer, a charge trap layer, a blocking insulating layer and a gate electrode on a semiconductor substrate. The tunneling insulating layer contacts a source and a drain formed by of impurity regions in the semiconductor substrate. The charge trap layer has a material composition that traps and stores electrical charge passing through the tunneling insulating layer. The blocking insulating layer blocks charge leakage between the charge trap layer and the gate electrode.

In the conventional charge-trap type flash memory device, programming is carried out as charge (e.g., electrons) passes through the tunneling insulating layer under the influence of an applied voltage and is trapped in the trap sites within the charge trap layer. In the charge-trap type flash memory device, a threshold voltage (Vth) varies in accordance with the presence of charge trapped in the charge trap layer. Thus, as the charge trap density of the charge trap layer increases, the quality of programming and erasing operations performed by the charge-trap type flash memory device are improved. Unfortunately, increased charge retention capabilities for conventional charge-trap type flash memory device are often accompanied by degradation of performance in other regards.

On the other hand, as the charge trap density provided by the charge trap layer decreases, the speed of programming and erasing operations performed by the charge-trap type flash memory device will decrease. Yet, reduced charge retention characteristics for a charge-trap type flash memory device offer other performance advantages. In sum, it is very difficult to simultaneously satisfy demands for improved efficiency in programming and erasing operation while also balancing the charge retention characteristics of a charge trapping material used in the fabrication of a charge-trap type flash memory device.

These difficulties are exacerbated by ongoing attempts to increase the overall integration density of memory cells forming flash memory devices and thereby increase the data storage capacity per unit area of such devices. For example, in order to increase the data storage capacity of flash memory devices, attempts have been made to decrease the overall size of individual memory cells by improving the photolithography processes used during fabrication.

However, reductions in the size of constituent nonvolatile memory cells risk alteration of the properties defining the various layers and regions forming the memory cells, such as the charge trapping layer, tunneling insulating layer, etc. Any defect in the tunneling insulating layer, will allow trapped charge to escape. As the overall size of nonvolatile memory cells is reduced, the thickness of the constituent tunneling insulating layer must also be reduced. Such layer “thinning” increases the possibility of charge loss from the charge trap layer. This is particularly true over the lifetime of the flash memory device as repeated programming, reading and erasing operations tend to degrade the tunneling insulating layer. This well understood temporal phenomenon is referred to as stress induced leakage current (SILC).

Of further note, many conventional flash memory devices incorporate a silicon-oxide-nitride-oxide-silicon (SONOS) type structure. More particularly, the silicon nitride layer in the SONUS type structure serves as the charge trapping layer. This type of flash memory device secures a relatively large memory window and has proven to be an effect design. However, charge loss due to stress induced leakage current (SILC) is particularly pronounced for this type of tunneling insulating layer following repeated memory device operations.

### SUMMARY OF THE INVENTION

Embodiments of the invention provide a flash memory device having improved charge storage capacity while preventing charge loss from a constituent charge trap layer caused by degradation of the tunneling insulating layer, regardless of its decreased thickness as required by contemporary and emerging charge-trap type flash memory devices characterized by reduced overall memory cell size.

Embodiments of the invention also provide a method of manufacturing a flash memory device that simply and easily forms a charge trap layer having a structure preventing charge loss from the charge trap layer under the foregoing conditions.

In one embodiment, the invention provides a flash memory device comprising; a tunneling insulating layer formed on a semiconductor substrate, a charge trap layer formed on the tunneling insulating layer, a blocking insulating layer formed on the charge trap layer, and a control gate electrode formed on the blocking insulating layer, wherein the charge trap layer comprises; at least one hybrid trap layer including a first trap layer formed from a first material having a first band gap energy, and a plurality of nano dots separated from each other, such that each nano dot is at least partially encircled by the first trap layer, wherein the plurality of nano dots is formed from a second material having a second band gap energy lower than the first band gap energy.

In another embodiment, the invention provides a method of manufacturing a flash memory device comprising; forming a tunneling insulating layer on a semiconductor substrate, forming a charge trap layer on the tunneling insulating layer, forming a blocking insulating layer on the charge trap layer, and forming a control gate electrode on the blocking insulating layer, wherein forming the charge trap layer comprises; forming at least one hybrid trap layer on the tunneling insulating layer, the hybrid trap layer comprising a first trap layer formed from a first material having a first band gap energy, and a plurality of nano dots separated from each other such that each nano dot is at least partially encircled by the first trap layer, wherein the plurality of nano dots is formed from a second material having a second band gap energy lower than the first band gap energy.

### BRIEF DESCRIPTION OF THE DRAWINGS

Embodiments of the invention will be described with reference to the attached drawings in which:

FIG. 1 is a sectional view illustrating a portion of a flash memory device according to an embodiment of the invention;

FIG. 2A is an enlarged sectional view of portion 11 indicated in FIG. 1 further illustrating an exemplary structure for a charge trap layer of the flash memory device, according to an embodiment of the invention;

FIG. 2B is a sectional view illustrating an exemplary structure of a charge trap layer of the flash memory device of FIG. 1, according to another embodiment of the invention;

FIG. 2C is a sectional view illustrating an exemplary structure of a charge trap layer of the flash memory device of FIG. 1, according to another embodiment of the invention;

FIG. 3 is a conceptual illustration of electrical potential in a gate stack structure of the flash memory device including the charge trap layer illustrated in FIG. 2A, according to another embodiment of the invention;

FIGS. 4A through 4H are sectional views illustrating a method of manufacturing a flash memory device according an embodiment of the invention;

FIG. 5 is a graph plot of hot temperature storage (HTS) characteristics of the gate stack structure of the flash memory device having diverse structures according to embodiments of the invention as compared with those of a comparative conventional example; and

FIG. 6 is a table illustrating evaluation results for the HTS characteristics and electric field characteristics during programming/erasing operations applied to structures of the charge trap layer in the gate stack structure in a flash memory device according to embodiments of the invention.

### DESCRIPTION OF EMBODIMENTS

Embodiments of the invention will now be described in some additional detail with reference to the accompanying drawings. The invention may, however, be embodied in many different forms and should not be construed as being limited to only the illustrated embodiments. Rather, these embodiments are presented as teaching examples. Throughout the drawings, the relative thickness of various layers and regions may have been exaggerated for clarity of illustration. Throughout the written description and drawings, like reference numbers are used to indicate like or similar elements, layers, and regions.

FIG. (FIG.) 1 is a sectional view illustrating a portion of a flash memory device 100 according to an embodiment of the invention.

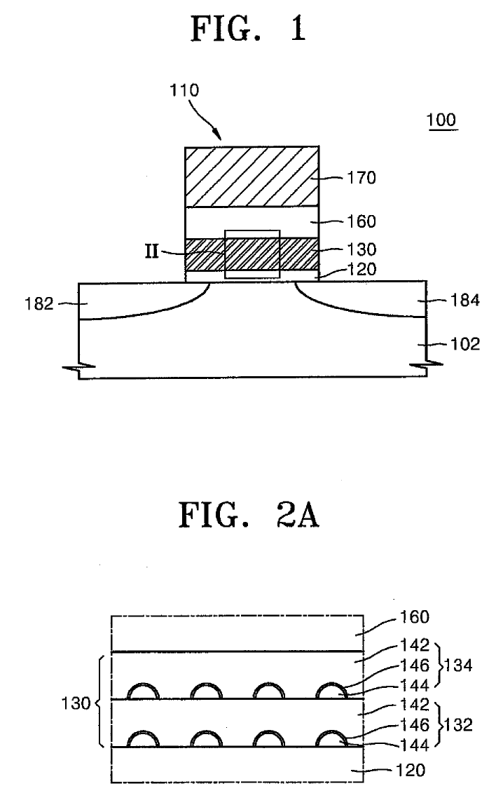

Referring to FIG. 1, the flash memory device 100 includes a gate stack structure 110 formed on a semiconductor substrate 102. The gate stack structure 110 includes a tunneling insulating layer 120 formed on the semiconductor substrate 102, a charge trap layer 130 formed on the tunneling insulating layer 120, a blocking insulating layer 160 formed on the charge trap layer 130, a blocking insulating layer 160 formed on the charge trap layer 130, and a control gate electrode 170 formed on the blocking insulating layer 160. Source/drain regions 182 and 184 are formed in the surface of the semiconductor substrate 102 on both sides of the gate stack structure 110.

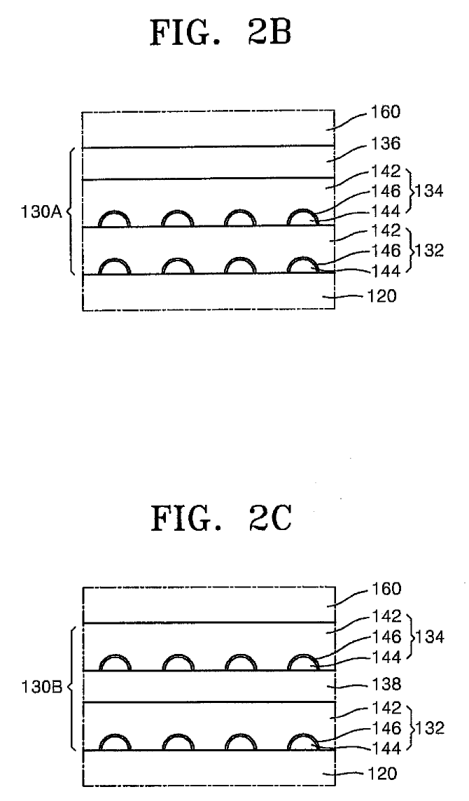

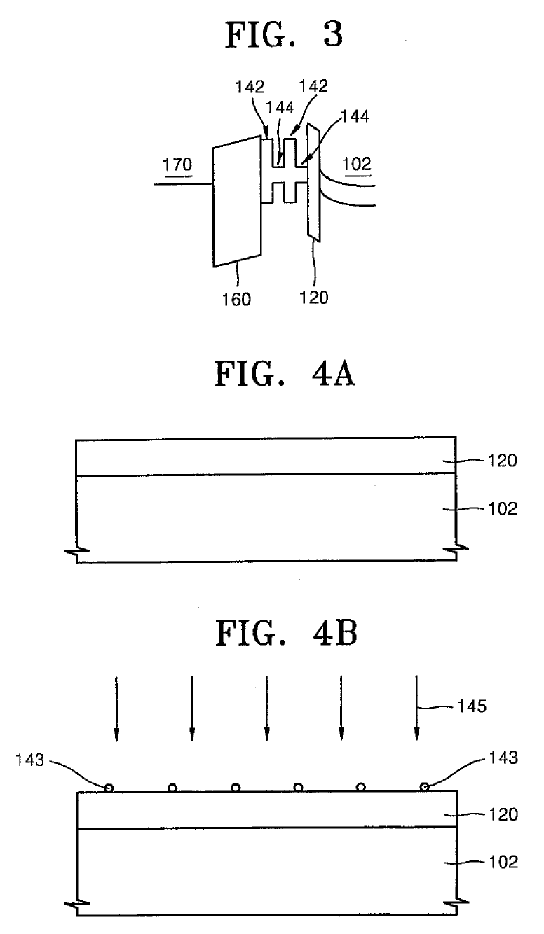

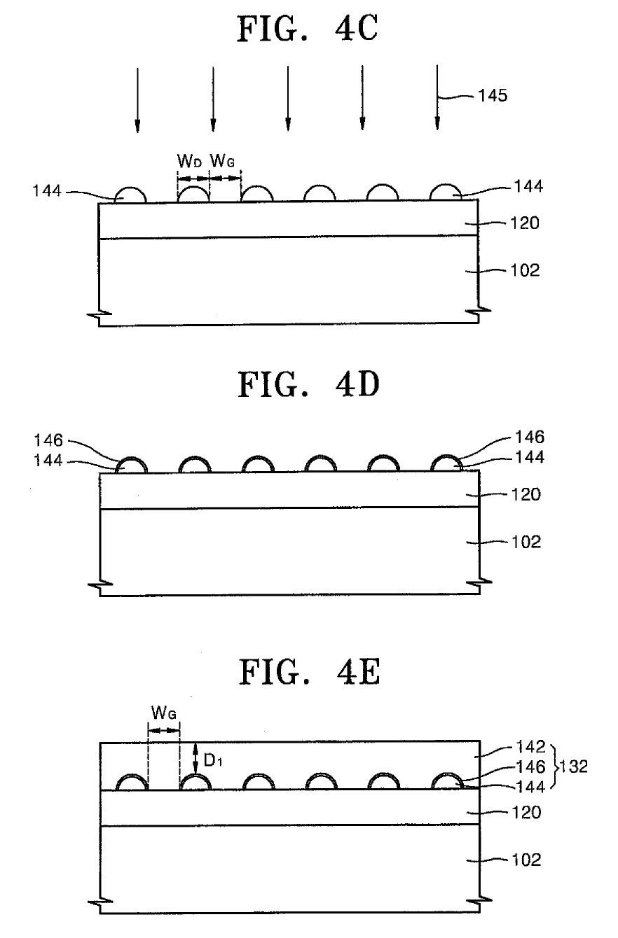

FIG. 2A is an enlarged sectional view of portion 11 indicated in FIG. 1 and serves to further illustrate one exemplary structure of the charge trap layer 130 according to an embodiment of the invention.

Referring to FIG. 2A, the charge trap layer 130 includes a first hybrid trap layer 132 and a second hybrid trap layer 134 sequentially formed on the tunneling insulating layer 120. The first hybrid trap layer 132 and the second hybrid trap layer 134 each include a first trap layer 142, which is film-shaped in certain embodiments, formed from a first material having a first band gap energy, and a plurality of nano dots 144 separated from each other by a predetermined distance while being at least partially encircled by the first trap layer 142. The nano dots 144 are formed from a second material having a second band gap energy lower than the first band gap energy. In this context and as used hereafter, the phrase “formed from” means that a particular element, layer or region is fabricated such that its material composition includes one or more of the indicated materials, either partially or wholly. For example, the first material forming the first trap layer 142 may be formed from at least one material selected from the group consisting of Si3N4, HfSiO, HfAlO and SiON. Otherwise, the first trap layer 142 may be a Si rich nitride (SRN) film and the SRN film denotes a layer having a Si/N atomic ratio greater than a Stoichiometric SU/N atomic ratio within the Si3N4 film.

The nano dots 144 may be formed from a semiconductor material or a metal or metal alloy. For example, the nano dots 144 may be formed from a semiconductor material such as Si, Ge and SiGe or a metal material such as W, WN, TaN, Co and Pt.

The nano dots 144 may have a nitride surface 146. However, the nitride surface 146 is not essential and can be omitted.

The nano dots 144 may each have a particle size ranging from between about several nanometers (nm) to several hundreds of nanometers (nm).

In the structure of the first hybrid trap layer 132 of FIG. 2A, the nano dots 144 are fully encircled by the tunneling insulating layer 120 and the first trap layer 142. Also, in the structure of the first hybrid trap layer 134, the nano dots 144 are fully encircled by the first material forming the first trap layer 142 in the second hybrid trap layer 134.

The nano dots 144 are generally arranged in the same horizontal plane of first trap layer 142 in the first hybrid trap layer 132 and the second hybrid trap layer 134.

Referring to FIG. 1, the tunneling insulating layer 120 may be formed from at least one material selected from the group consisting of SiO2, SiON, HfO2, HfSiO and ZrO2 or a combination of these materials. The blocking insulating film 160 may be formed from at least one material selected from the group consisting of Al2O3, SiO2, HfO2, ZrO2, LaO, LaAlO, LaHfO and HfAlO. The control gate electrode 170 may be formed from at least one material selected from the group consisting of TaN, TiN, W, WN, HfN and tungsten silicide.

Although the example of charge trap layer 130 illustrated in FIG. 2A includes two hybrid trap layers (i.e., the first hybrid trap layer 132 and the second hybrid trap layer 134), the present invention is not limited to only this particular structure. Rather, any charge trap layer 130 including one or more hybrid trap layers will fall within the scope of the present invention. Also, a hybrid trap layer formed from a material identical to the first material forming the first trap layer 142 may be interposed between respective hybrid trap layers. In this context, the term “identical” means substantially the same type of material, not necessarily an atomically exact identity between the two material regions.

FIG. 2B is a sectional view illustrating an exemplary structure for a charge trap layer 130A which may be incorporated into a flash memory device designed and implemented in accordance with an embodiment of the invention. Charge trap layer 130A is a possible alternative to the charge trap layer 130 shown in FIG. 2A.

The structure illustrated in FIG. 2B is similar to that of the charge trap layer 130 of FIG. 2A except that a capping trap layer 136 is interposed between the second hybrid trap layer 134 and the blocking insulating layer 160 in the charge trap layer 130 illustrated in FIG. 2A. The capping trap layer 136 may be formed from at least one material selected from the group consisting of Si3N4, HfSiO, HfAlO, SRN and SiON. The capping trap layer 136 may be formed from a material identical to that forming the first trap layer 142.

FIG. 2C is a sectional view illustrating an exemplary structure for a charge trap layer 130B which may be incorporated into a flash memory device designed and implemented in accordance with an embodiment of the invention. Charge trap layer 130B is a possible alternative to the charge trap layer 130 shown in FIG. 2A and the charge trap layer 130A in FIG. 2B.

The structure illustrated in FIG. 2C is similar to that of the embodiment illustrated in FIG. 2A except that an intermediary trap layer 138 is interposed between the first hybrid trap layer 132 and the second hybrid trap layer 134 in the charge trap layer 130 illustrated in FIG. 2A. The intermediary trap layer 138 may be formed from at least one material selected from the group consisting of Si3N4, HfSiO, HfAlO, SRN and SiON. Alternatively, the intermediary trap layer 138 may be formed from a material identical to that forming the first trap layer 142.

Although not illustrated, the charge trap layer 130 illustrated in FIG. 2A may further include a lower trap layer (not shown) between the first hybrid trap layer 132 and the tunneling insulating layer 120. The lower trap layer may be formed from at least one material selected from the group consisting of Si3N4, HfSiO, HfAlO, SRN and SION. Alternatively, the lower trap layer may be formed from a material identical to that forming the first trap layer 142.

If the lower trap layer is not formed between the first hybrid trap layer 132 and the tunneling insulating layer 120, the first hybrid trap layer 132 contacts the tunneling insulating layer 120 as illustrated in FIGS. 2A, 2B and 2C. Also, the nano dots 144 are fully encircled by the tunneling insulating layer 120 and the first trap layer 142 in the first hybrid trap layer 132.

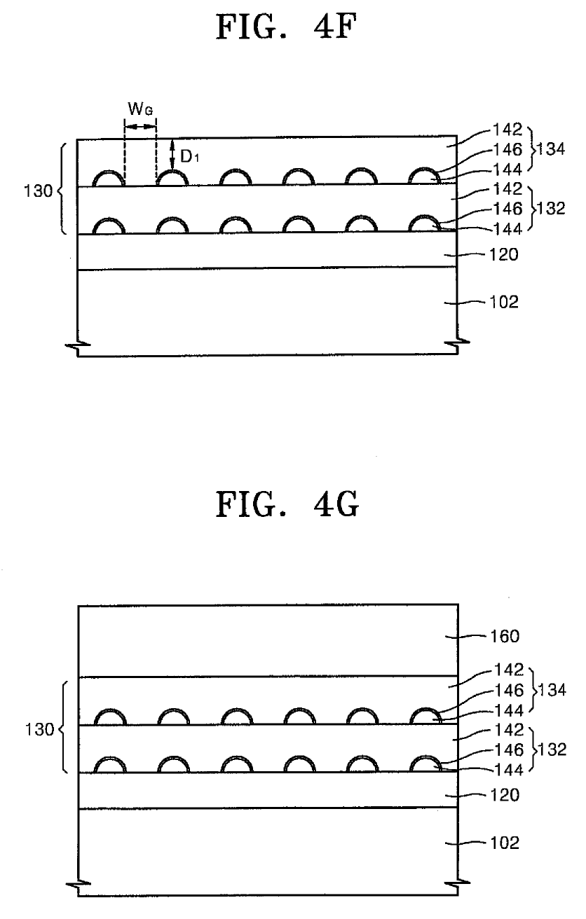

FIG. 3 is a conceptual illustration of electrical potential in the gate stack structure of the flash memory device 100 including the charge trap layer 130 illustrated in FIG. 2A, according to an embodiment of the invention.

As illustrated in FIG. 3, the nano dots 144 have a band gap energy that is lower than that of the first trap layer 142, and are formed adjacent to the tunneling insulating layer 120. Thus, charge is trapped at a low trap level thereby increasing charge trap energy. Moreover, the number of charge trap sites is increased within the charge trap layer 120 to improve reliability of the flash memory device 100. Particularly, the nano dots 144, formed from silicon (Si), have a trap level deeper by about 1˜2 eV than a conduction band of the SiO2 layer, and deeper by about 1˜2 eV than a conduction band of the Si3N4 layer. Also, the charge trapped within the charge trap layer 130 is discontinuously distributed by the nano dots 144. Therefore, even if a defect occurs in the tunneling insulating layer 120, the defect will not adversely impact the entire charge trap layer 130 with charge loss effects the way a similar defect would in conventional devices.

In the exemplary charge trap layers 130, 130A and 130B illustrated in FIGS. 2A, 2B and 2C, the nano dots 144 have a lower band gap energy than that of the first trap layer 142, and thus, act as a potential well with respect to the first trap layer 142. Hence, in the charge trap layer 130, charge is trapped in the low trap level due to the relatively low conduction band (Ec) of the nano dots 144, thereby improving the charge retention characteristics of the device.

Certain functional aspects of the respective elements forming the charge trap layer 130 illustrated in FIG. 2A will now be described.

First, the nano dots 144 on the first hybrid trap layer 132 are formed from a material with a band gap energy lower than that of the first trap layer 142, thereby providing a deep trap level and improving the charge retention characteristics. Also, the potential well formed in the charge trap layer 130 is provided by the nano dots 144, so that the charge loss caused by the leakage of thermally activated charge to the tunneling insulating layer 120 after programming can be decreased.

The first trap layer 142 in the first hybrid trap layer 132 separates the nano dots 144 from each other. Accordingly, the nano dots 144 are formed within the first trap layer 142 at a relatively high density to increase charge storage capacity.

The density of the nano dots 144 within the charge trap layer 130 can be increased by the nano dots 144 in the second hybrid trap layer 134. Hence, the nano dots 144 in the second hybrid trap layer 134 improve the charge storage capacity of the charge trap layer 130.

The first trap layer 142 in the second hybrid trap layer 134 impedes the loss of the charge trapped in the nano dots 144 in the second hybrid trap layer 134 through the blocking insulating layer 160. Also, the blocking insulating layer 160, which in one embodiment is formed from a metal oxide layer such as Al2O3, prevents degradation in the charge trapping characteristics of the nano dots 144 due to the formation of oxidized surfaces of the nano dots 144 during forming the blocking insulating layer 160.

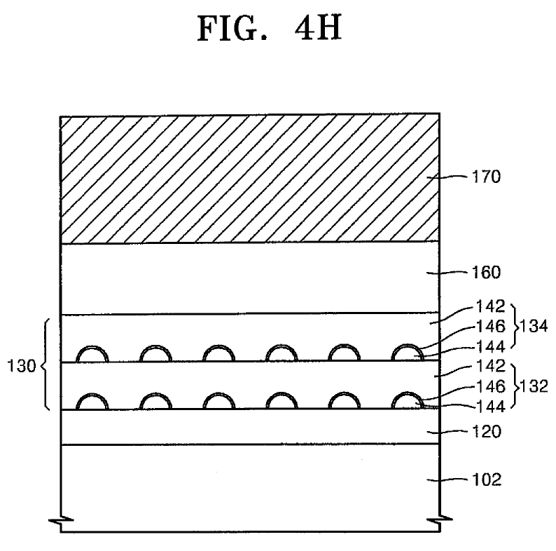

FIGS. 4A through 4H are related sectional views illustrating a method of manufacturing a flash memory device according an embodiment of the invention.

Referring to FIG. 4A, the tunnelling insulating layer 120 is formed on the semiconductor substrate 102. The tunnelling insulating film 120 may be formed from at least one material selected from the group consisting of SiO2, SiON, HfO2, HfSiO and ZrO2 to a thickness of about 20˜70 Å.

Referring to FIG. 4B, a nano dot source gas 145 is supplied onto the tunneling insulating layer 120 to form a plurality of nano dot seeds 143 that are separated from each other over the tunneling insulating layer 120.

If the nano dot seeds 143 are formed from silicon (Si), the silicon source gas may be supplied on the tunneling insulating layer 120 for a predetermined time of about 1-2 minutes at a constant ambient temperature of about 500˜550° C., for example. The silicon source gas may be at least one gas selected from the group consisting of SiH4, SI2H6 and SiH2Cl2. While forming the nano dot seeds 143, a constant ambient pressure of about 0.1˜10 Torr may established, for example.

Referring to FIG. 4C, the nano dot seeds 143 are grown while supplying the nano dot source gas 145 onto a resultant structure having the nano dot seeds 143 thereon, and thereby, forming the nano dots 144 separated from each other. For example, if the nano dots seeds 143 are formed from silicon, the nano dots 144 will be crystalline silicon dots.

In order to form the nano dots 144 composed of the crystalline silicon dots, the silicon seeds may be grown by supplying the silicon source gas onto the resultant structure formed with the silicon seeds thereon by maintaining a pressure of about 0.1˜10 Torr at a temperature of about 570˜600° C. for about 15˜20 minutes. Specifically, the nano dots 144 each may have a particle size WD of about 5 nm. Also, the nano dots 144 may be formed so as to maintain an approximate mean distance WG between respective nano dots 144 by about 5 nm.

Referring to FIG. 4D, the surfaces of the nano dots 144 are subjected to nitridation. By doing so, nitride surfaces 146 are formed on the nano dots 144. The nitride surfaces 146 of the nano dots 144 prevent the forming of an undesired natural oxide layer on the surfaces of the nano dots 144 when transferring a wafer prior to performing following processing. Furthermore, while nitriding the surfaces of the nano dots 144, the silicon residuals which are possibly left on an upper surface of the tunneling insulating layer 120 between respective nano dots 144 are nitrided, so that the nano dots 144 can maintain the mutually separate dotted shape.

However, the nitridation of the surfaces of the nano dots 144 may be omitted in some embodiments of the invention.

Referring to FIG. 4E, the first trap layer 142, encircling the nano dots 144 and film-shaped, is formed on the resultant structure on which the nano dots 144 are formed.

The first trap layer 142 may be formed from at least one material selected from the group consisting of Si3N4, HfSiO, HfAlO, SRN and SiON. The first trap layer 142 may cover the nano dots 144 to a thickness D1 that is similar to the distance WG between respective nano dots 144 formed on the tunneling insulating layer 120. In order to form the first trap layer 142, a low pressure chemical vapor deposition (LPCVD) or atomic layer deposition (ALD) process may be performed, for example.

Referring to FIG. 4F, the second hybrid trap layer 134 is formed on the first hybrid trap layer 132 using the same method as described with reference to FIGS. 4B through 4E.

The second hybrid trap layer 134 includes, similarly to the first hybrid trap layer 132, the nano dots 144 with the nitride surfaces 146 and the first trap layer 142 encircling the nano dots 144. In the second hybrid trap layer 134, the first trap layer 142 may cover the nano dots 144 to the thickness D1 that is similar to the distance WG between respective nano dots 144 formed on the first hybrid trap layer 132.

The first hybrid trap layer 132 and the second hybrid trap layer 134 form the charge trap layer 130. In the current embodiment, the charge trap layer 130 structure as illustrated in FIG. 2A is formed. If the capping trap layer 136 illustrated in FIG. 2B or the intermediary trap layer 138 illustrated in FIG. 2C is formed, the capping trap layer 136 and the intermediary trap layer 138 may be each formed by an LPCVD or an ALD process.

Referring to FIG. 4G, the blocking insulating layer 160 is formed on the charge trap layer 130. The blocking insulating layer 160 may be a high-k film having a higher dielectric constant than that of a silicon nitride layer. For example, the blocking insulating layer 160 may be a metal oxide layer, a metal nitride layer or a combination of these layers. The blocking insulating layer 160 may have a thickness of about 40˜300 Å.

The blocking insulating layer 160 may be formed by a physical vapor deposition (PVD), an atomic layer deposition (ALD) or a chemical vapor deposition (CVD) process. The blocking insulating layer 160 may be formed from at least one material selected from the group consisting of Al2O3, SiO2, HfO2, ZrO2, LaO, LaAlO, LaHfO and HfAlO.

Referring to FIG. 4H, a conductive material is deposited on the blocking insulating layer 160 to form a gate electrode 170. The control gate electrode 170 may be formed from at least one material selected from the group consisting of TaN, TiN, W, WN, HfN and tungsten silicide.

Thereafter, the control gate electrode 170, the blocking insulating layer 160, the charge trap layer 130 and the tunneling insulating layer 120 are sequentially patterned to form a gate stack structure 110 as illustrated in FIG. 1. Then, impurities are implanted into the surface of the semiconductor substrate 102 exposed in both sides of the gate stack structure 110, which is then thermally treated to form the source/drain regions 182 and 184 as illustrated in FIG. 1.

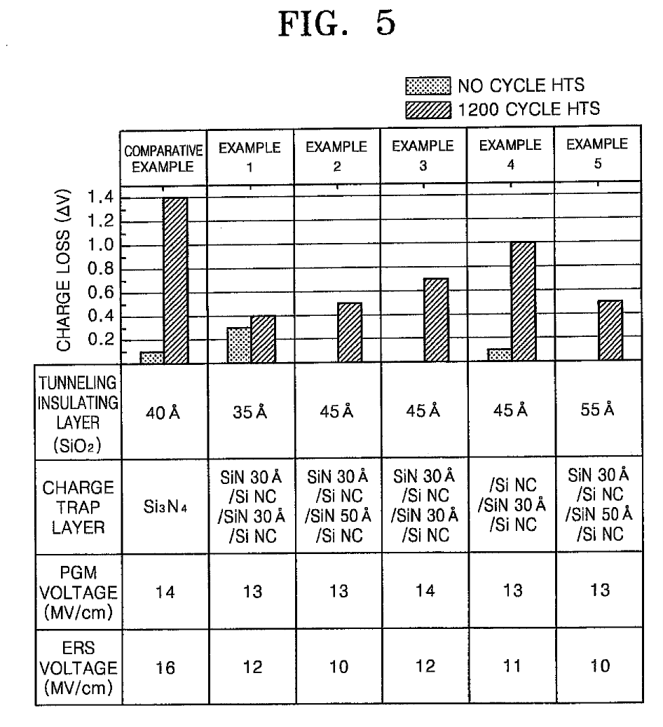

FIG. 5 is a graph plot of hot temperature storage (HTS) characteristics of the gate stack structure of the flash memory device having diverse structures consistent with embodiments of the invention as compared with those of a comparative conventional example.

Referring to FIG. 5, the charge trap layer of Example 1 was obtained as follows. A plurality of silicon nanocrystals (designated as “Si NC” in FIG. 5) having a diameter of about 5 nm were formed on a tunneling insulating layer formed from SiO2 in distances of about 5 nm from each other. Then, a Si3N4 layer (designated as “SiN” in FIG. 5) was formed to a thickness of 30 Å by an LPCVD process to form a first hybrid trap layer. After repeatedly forming the silicon nanocrystals having a diameter of about 5 nm on the first hybrid trap layer, a Si3N4 layer was formed thereon to a thickness of 30 Å by an ALD process, and thereby, forming a second hybrid trap layer.

Example 2 shows a case similar to Example 1 except that the Si3N4 layer forming the first hybrid trap layer was formed to a thickness of 50 Å.

Example 3 shows a case of forming the charge trap layer similar to Example 1.

Example 4 is a case of omitting the forming of the Si3N4 layer after forming the silicon nanocrystals Si NC when forming the second hybrid trap layer.

Example 5 shows a case of forming the charge trap layer similar to Example 2. The comparative example shows a charge trap layer formed of a Si3N4 layer to a thickness of 70 Å.

In respective Examples 1 through 5 and the comparative example, an Al2O3 layer to a thickness of 200 Å was formed on the charge trap layer and then annealed at a temperature of about 1050° C. for about 2 minutes to form a blocking insulating layer, and a TaN layer of about 200 Å was formed thereon to form a control gate electrode. In each case, the gate stack structure had a size of 1 μm both in length and width.

In order to obtain the result of FIG. 5, a charge loss was calculated from ΔVth respectively measured for two cases of gale stack structure of before and after a 1200 cycles operation. The case of the 1200 cycle operation was baked at a temperature of 200° C. for 2 hours before the measurement.

As described in FIG. 5, in Examples 1 through 5 having a gate stack structure for the flash memory device consistent with an embodiment of the invention, the film-shaped trap layer formed from the Si3N4 layer, and the hybrid trap layer including a plurality of nano dots consisting of the silicon nanocrystals encircled by the trap layer and having a band gap energy at a lower level than that of the Si3N4 layer were formed as the charge trap layer, and thereby, greatly decreasing a charge loss. Particularly, when Examples 1, 2, 3 and 5 are compared to Example 4, the charge loss could be more effectively prevented in the case where the Si3N4 layer was formed on the second hybrid trap layer rather than omitting the Si3N4 layer. Also, if Examples 1 and 3 are compared to each other and Examples 2 and 5, are compared to each other, no charge was lost before applying hot temperature storage (HTS) characteristics when the thickness of the tunneling insulating layer was increased in case of the same conditions as the charge trap layer. Furthermore, in Examples 1 through 5, the charge trap layer was operable at a lower operation voltage than that of the comparative example.

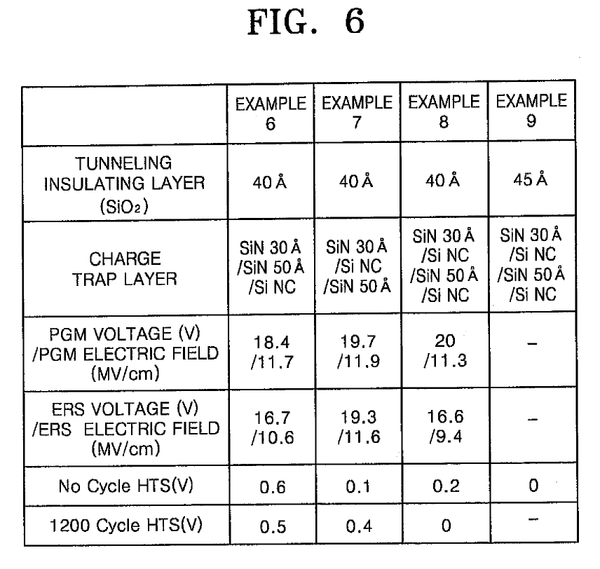

FIG. 6 is a table illustrating results of evaluating the HTS characteristics and electric field characteristics during programming/erasing applied to the charge trap layer of the gate stack structures of the flash memory device designed and fabricated in accordance with embodiments of the invention.

In FIG. 6, the charge trap layer of Example 6 was similar to that of Example 1 except that the Si3N4 layer forming the first hybrid trap layer was formed to a thickness of 50 Å, and the forming of the silicon nano dots forming the second hybrid trap layer was not carried out.

Example 7 was similar to Example 1, however, the forming of the silicon nano dots is omitted and the Si3N4 layer forming the first hybrid trap layer was formed to a thickness of 50 Å.

Example 8 was similar to Example 1, however, the Si3N4 layer forming the first hybrid trap layer is formed to a thickness of 50 Å.

In respective Examples 6, 7 and 8, the SiO2 layer was formed to a thickness of 40 Å as the tunneling insulating layer.

Example 9 was similar to Example 8 except that the SiO2 layer was formed having a thickness of 45 Å as the tunneling insulating layer.

From the evaluation results of FIG. 6, it can be noted that the HTS characteristics and the electric field characteristics during programming/erasing operations are excellent when two hybrid trap layers are formed in the charge trap layer as Example 8. Also, in Example 9 having the charge trap layer under the same conditions as the charge trap layer of Example 8, there was no charge loss during erasing when the thickness of the tunneling insulating layer was increased by 45 Å.

A flash memory device according to an embodiment of the invention will include a hybrid trap layer as a charge trap layer. The hybrid trap layer may include a film-shaped first trap layer formed from a first material having a band gap energy of a first level, and a plurality of nano dots which are separated from each other by a predetermined distance under a state of being partially encircled by the first trap layer and are formed from a second material having a band gap energy lower than the first level. Therefore, the nano dots having the band gap energy lower than the first trap layer are formed adjacent to the tunnelling insulating layer in flash memory devices according to embodiments of the invention, so that charge may be trapped at a low trap level in order to improve charge retention characteristics. Also, charge trap sites are increased within the charge trap layer to improve the reliability of the flash memory device. Furthermore, the charge trap density for the charge trap layer is improved in order to increase a charge storage capacity, and multilevel cells will be more easily fabricated.

While the present invention has been particularly shown and described with reference to exemplary embodiments thereof, it will be understood by one of ordinary skill in the art that various changes in form and details may be made therein without departing from the scope of the present invention as defined by the following claims.

What is claimed is:

1. A flash memory device comprising:
a tunneling insulating layer formed on a semiconductor substrate;
a charge trap layer formed on the tunneling insulating layer;
a blocking insulating layer formed on the charge trap layer; and
a control gate electrode formed on the blocking insulating layer,
wherein the charge trap layer comprises:
at least one hybrid trap layer including a first trap layer formed from a first material having a first band gap energy, and
a plurality of nano dots separated from each other, such that each nano dot is at least partially encircled by the first trap layer, wherein the plurality of nano dots is formed from a second material having a second band gap energy lower than the first band gap energy.

2. The flash memory device of claim 1, wherein the at least one hybrid trap layer contacts the tunneling insulating layer; and
the nano dots in the first hybrid trap layer are fully encircled by the first material and the tunneling insulating layer.

3. The flash memory device of claim 1, wherein at least one hybrid trap layer includes a first hybrid trap layer contacting the tunneling insulating layer, and a second hybrid trap layer formed on the first hybrid trap layer;
the nano dots formed in the first hybrid trap layer are fully encircled by the first material of the first trap layer and the tunneling layer, respectively; and
the second hybrid trap layer is fully encircled by the first material of the first trap layer.

4. The flash memory device of claim 1, wherein the plurality of nano dots in the hybrid trap layer includes a plurality of first nano dots arranged in the same horizontal plane within the first trap layer.

5. The flash memory device of claim 1, wherein the first trap layer in the hybrid trap layer is formed from at least one material selected from the group consisting of Si3N4, HfSiO, HfAlO, SRN (Si rich nitride) and SiON.

6. The flash memory device of claim 1, wherein the plurality of nano dots in the hybrid trap layer is formed from a semiconductor material, a metal, or a metal alloy.

7. The flash memory device of claim 6, wherein the plurality of nano dots in the hybrid trap layer is formed from at least one material selected from the group consisting of Si, Ge, SIGe, W, WN, TaN, Co and Pt.

8. The flash memory device of claim 6, wherein each one of the plurality of nano dots comprises a nitrided surface.

9. The flash memory device of claim 1, wherein the charge trap layer further comprises a second trap layer and covering at least a portion of the hybrid trap layer, and
the second trap layer is formed from a material identical to that of the first trap layer.

10. The flash memory device of claim 9, wherein the charge trap layer comprises a first hybrid trap layer and a second hybrid trap layer stacked on the first hybrid trap layer, and
the second trap layer is interposed between the first hybrid trap layer and the second hybrid trap layer.

11. The flash memory device of claim 1, further comprising:
a third trap layer interposed between the hybrid trap layer and the blocking insulating layer,
wherein the third trap layer is formed from a material identical to that of the first trap layer.

12. The flash memory device of claim 1, further comprising:
a fourth trap layer interposed between the tunneling insulating layer and the hybrid trap layer,
wherein the fourth trap layer is formed from a material identical to that of the first trap layer.

13. The flash memory device of claim 9, wherein the first trap layer is formed from at least one material selected from the group consisting of Si3N4, HfSiO, HfAlO, SRN (Si rich nitride) and SiON.

14. The flash memory device of claim 1, wherein the tunneling insulating layer is formed from at least one material selected from the group consisting of SiO2, SiON, HfO2, HfSiO and ZrO2.

15. The flash memory device of claim 1, wherein the blocking insulating layer is formed from at least one material selected from the group consisting of Al2O3, SiO2, HfO2, ZrO2, LaO, LaAlO, LaHfO and HfAlO.

16. The flash memory device of claim 1, wherein the control gate electrode is formed from at least one material selected from the group consisting of TaN, TiN, W, WN, HfN and tungsten silicide.

17. A method of manufacturing a flash memory device comprising:
forming a tunneling insulating layer on a semiconductor substrate;
forming a charge trap layer on the tunneling insulating layer;
forming a blocking insulating layer on the charge trap layer; and
forming a control gate electrode on the blocking insulating layer,
wherein forming the charge trap layer comprises;
forming at least one hybrid trap layer on the tunneling insulating layer, the hybrid trap layer comprising a first trap layer formed from a first material having a first band gap energy, and a plurality of nano dots separated from each other such that each nano dot is at least partially encircled by the first trap layer, wherein the plurality of nano dots is formed from a second material having a second band gap energy lower than the first band gap energy.

18. The method of claim 17, wherein the plurality of nano dots is formed from a semiconductor material, a metal or a metal alloy.

19. The method of claim 18, wherein the plurality of nano dots is formed from at least one material selected from the group consisting of Si, Ge, SiGe, W, WN, TaN, Co and Pt.

20. The method of claim 17, wherein the forming of the charge trap layer comprises:
forming a plurality of first nano dots arranged on a same horizontal plane on the tunneling insulating layer; and
depositing the first material on the first nano dots to form the first trap layer which encircles the first nano dots.

21. The method of claim 20, wherein the forming of the first nano dots comprises:
forming a plurality of nano dot seeds that are separate from each other on the tunneling insulating layer; and
growing the nano dot seeds to form the first nano dots that are separate from each other on the tunneling insulating layer.

22. The method of claim 21, after the forming of the first nano dots, further comprising nitriding the surfaces of the first nano dots.

23. The method of claim 17, wherein the at least one hybrid trap layer includes a first hybrid trap layer contacting the tunneling insulating layer, and the forming of the charge trap layer comprises:
forming the first hybrid trap layer on the tunneling insulating layer; and
forming the second trap layer from the first material on the first hybrid trap layer.

24. The method of claim 17, wherein the at least one hybrid trap layer includes a first hybrid trap layer formed to contact the tunneling insulating film, and a second hybrid trap layer formed on the first hybrid trap layer, and
the second hybrid trap layer contacts an upper surface of the first hybrid trap layer.

25. The method of claim 17, wherein the at least one hybrid trap layer comprises a first hybrid trap layer formed to contact with the tunneling insulating layer, and a second hybrid trap layer formed on the first hybrid trap layer, and forming of the charge trap layer comprises:
forming the first hybrid trap layer;
forming a second trap layer from a material identical to that forming the first trap layer on the first hybrid trap layer; and
forming the second hybrid trap layer on the second trap layer.

26. The method of claim 25, wherein the forming of the charge trap layer further comprises:
forming a third trap layer from material identical to that forming the first trap layer on the second hybrid trap layer.

27. The method of claim 17, wherein the first trap layer in the hybrid trap layer is formed from at least one material selected from the group consisting of Si3N4, HfSiO, HfAlO, SRN (Si rich nitride) and SiON.

28. The method of claim 17, wherein the tunneling insulating layer is formed from at least one material selected from the group consisting of SiO2, SiON, HfO2, HfSiO and ZrO2.

29. The method of claim 17, wherein the blocking insulating layer is formed from at least one material selected from the group consisting of Al2O3, SiO2, HfO2, ZrO2, LaO, LaAlO, LaHfO and HfAlO.

30. The method of claim 17, wherein the control gate electrode is formed from at least one material selected from the group consisting of TaN, TiN, W, WN, HfN and tungsten silicide.
